(19) United States
(12) Patent Application Publication
(10) Pub. No.: US 2002/0125515 A1
(43) Pub. Date: Sep. 12, 2002

(54) Field effect transistor using zirconiumtitanate thin film

(76) Inventors: Seung Ki Joo, Seoul (KR); Jung Ho Park, Seoul (KR)

Correspondence Address: ROSENBERG, KLEIN & LEE, 3458 ELLICOTT CENTER DRIVE-SUITE 101, ELLICOTT CITY, MD, 21043, US

(21) Appl. No.: 09/920,637

(22) Filed: Aug. 3, 2001

(30) Foreign Application Priority Data
Jan. 19, 2001 (KR) 2001-3294

(51) Int. Cl. H01L 29/94

(52) U.S. Cl. 257/295

(57) ABSTRACT

The present invention relates to a field effect transistor device using ZrTiO₄ for a diffusion barrier layer or a buffer layer of ferroelectrics. The field effect transistor device of the present invention comprises a buffer layer made of ZrTiO₄ on a Si substrate and a ferroelectric dielectric layer comprising PZT formed on top of the buffer layer, and additionally a metal layer made of platinum in-between the PZT layer and the buffer layer. The device of the present invention shows superior interfacial characteristics between the PZT and the buffer layer by employing a buffer layer of ZrTiO₄ comprising Zr and Ti which are components of PZT, the ferroelectric dielectric layer. Furthermore, the device of the present invention has improved characteristics by using the buffer layer that prevents a reaction between the PZT and the semiconductor substrate.

### BACKGROUND OF THE INVENTION

1. Field of the Invention

The present invention relates to a field effect transistor (FET) and especially to a field effect transistor applied to a non-volatile memory device by equipping with a ferroelectric layer.

2. Description of Related Art

Recently, interests on a non-volatile memory device applied with a ferroelectric layer are increasing according to the development of technologies in thin film formation (hereinafter, the non-memory device applied with a ferroelectric layer is referred to a ‘ferroelectric memory device’.) The ferroelectric memory device utilizes polarization inversion of ferroelectrics and its residual polarization, and is capable of high speed reading and writing.

The polarization inversion of ferroelectrics results from rotation of a permanent dipole the operation speed of ferroelectric memory device is faster than other non-volatile memory device such as EEPROM (electrically erasable programmable read only memory) device or a flash memory by 10⁴ to 10⁵, and especially through a micro and optimal designing the operation speed in the range of several tens to several hundreds nsec which is comparable to DRAM (dynamic random access memory) is achieved. Furthermore, voltage as low as 2 to 5 V is sufficient for voltage for polarization inversion of ferroelectrics in a ferroelectric memory device, and therefore, it can be operated at a lower voltage compared to EEPROM or flash memory devices which require as high as 10 to 12 V.

The ferroelectric memory device can be divided into a destructive read out, DRO, type which destructs stored information once it is read and a non-destructive read out, NDRO, type which does not destruct stored information after it is read. Usually, the DRO type ferroelectric memory device reads stored information by measuring accumulated charge in the ferroelectric capacitor, and the NDRO type ferroelectric memory device reads stored information by measuring channel conductance of field effect transistor applied with ferroelectrics for a gate insulator.

Currently, PZT is widely used for ferroelectric material that is a core in ferroelectric memory device. One of the difficulties in the manufacturing process of a device using PZT is to prevent a reaction and diffusion of Pb which is contained in PZT with neighboring parts due to high chemical reactivity of Pb. The reaction and diffusion are serious between a gate insulator and silicon which forms a channel of a transistor in the manufacturing of the NDRO type ferroelectric memory device. Therefore, currently a device of an MFIS (metal-ferroelectric-insulator-semiconductor) structure which has insulators such as CeO₂, Y₂O₃ or YSZ (Yttria Stabilized Zirconia) deposited on Si surface in the manufacturing of the NDRO type ferroelectric memory device and uses the deposited insulator for a diffusion barrier between a semiconductor substrate and PZT, or a device of an MFMIS (metal-ferroelectric-metal-insulator-semiconductor) structure which has an electrode such as Pt or Ir/IrO₂ deposited on the insulator layer are proposed. FIG. 1 and FIG. 2 represents the devices as described above.

FIG. 1 is a cross-sectional view to illustrate a device with an MFIS structure using CeO₂, Y₂O₃ or YSZ as a diffusion barrier layer, and FIG. 2 is a cross-sectional view to illustrate a device with an MFMIS structure deposited with an electrode such as Pt or Ir/IrO₂ on the insulator layer with the diffusion barrier layer such as CeO₂, Y₂O₃ or YSZ. Specifically, the device with MFIS structure comprises a silicon substrate 1, ferroelectrics 2 formed on top of the substrate and a top electrode 3, and additionally a diffusion barrier layer 4 such as CeO₂, Y₂O₃ or YSZ between the silicon substrate 1 and the ferroelectrics 2. The top electrode 3 is usually made of Pt. Hereinafter, the diffusion barrier layer is referred to a ‘buffer layer’. The device of the MFMIS structure is a structure with an electrode such as Pt or Ir/IrO₂ inserted between the buffer layer and the ferroelectrics in the device of the MFIS structure.

In case of the non-volatile field effect transistor, higher dielectric constant of an insulation layer is beneficial to the operation a device, but the dielectric constant of CeO₂, Y₂O₃ or YSZ is not high enough and their diffusion barrier properties are not superior.

### SUMMARY OF THE INVENTION

Therefore, it is an object of the present invention to provide a field effect transistor using a dielectric material with superior diffusion barrier and dielectric properties and its manufacturing method.

To this end, the present invention provides a manufacturing method of a field effect transistor using zirconiumtitanate(ZrTiO₄) thin film comprising:

a step of forming ZrTiO₄ thin film on a semiconductor substrate as a buffer layer;

a step of forming a ferroelectric thin film on the buffer layer; and

a step of forming a top electrode on the ferroelectric thin film.

Furthermore, the present invention provides a field effect transistor using zirconiumtitanate thin film comprising a semiconductor substrate, a buffer layer formed of zirconiumtitanate on the semiconductor substrate, a ferroelectric thin film formed on the buffer layer and a top electrode formed on the ferroelectric thin film.

The field effect transistor of the present invention uses ZrTiO₄ for a diffusion barrier layer or a buffer layer of ferroelectrics.

The ZrTiO₄ layer or the ferroelectric thin film can be deposited on a Si substrate or a capacitor by methods such as Metal Organic Chemical Vapor Deposition (MOCVD), sputtering, sol-gel, Metal Organic Decomposition (MOD), evaporation or laser ablation.

A step of forming a gate insulator between the semiconductor substrate and the buffer layer can be added.

The field effect transistor device comprises a bottom layer containing Si, a ferroelectric thin film formed on the bottom layer, a ZrTiO₄ layer formed between the ferroelectric thin film and the bottom layer and optionally an electrode layer such as a Pt layer between the bottom layer and the ZrTiO₄ layer.

ZrTiO₄ is a material with α-PbO₂ type orthorhombic structure, and has a crystallographic space group of Pbcn in Hermann-Mauguin notation. Its dielectric constant is about 40. Unlike binary compounds such as TiO₂ or ZrO₂, ZrTiO₄ is a ternary compound, and its Gibb's free energy of formation is similar to those of ferroelectric thin film such as PZT, and under the diffusion of Pb, ZrTiO₄ does not react with Pb to form a new compound. Therefore, ZrTiO₄ has superior kinetic and thermodynamic properties compared to other diffusion barrier layer, and can meet the requirements for a diffusion barrier layer occurred in the manufacturing of a device utilizing ferroelectrics such as PZT.

### BRIEF DESCRIPTION OF THE DRAWINGS

FIG. 1 is a cross-sectional view of a field effect transistor of a prior art using CeO₂, Y₂O₃ or YSZ as a diffusion barrier layer.

FIG. 2 is a cross-sectional view of a field effect transistor of a prior art wherein an electrode is inserted between ferroelectrics and the diffusion barrier layer.

FIG. 3 is an XRD (X-ray diffraction) pattern of a PZT thin film deposited on Si substrate by a sputtering method.

FIG. 4 is an XRD pattern of a PZT thin film deposited with ZrTiO₄ on Si substrate according to the present invention.

FIG. 5 is an AES depth concentration profile of Pb, Zr, Ti, O and Si in the PZT/ZrTiO₄/Si structure according to the present invention.

FIG. 6 is a graph illustrating changes in dielectric constant of PZT/ZrTiO₄ thin film according to the PZT crystallization time and the thickness of ZrTiO₄ thin film according to the present invention.

FIG. 7 is a capacitance-voltage, C-V, characteristics curve according to the thickness of ZrTiO₄ thin film in the PZT/ZrTiO₄/Si structure according to the present invention.

FIG. 8 is a residual polarization according to the thickness of ZrTiO₄ thin film in the PZT/ZrTiO₄/Si according to the present invention.

FIG. 9 is a cross-sectional view of a field effect transistor using ZrTiO₄ for a buffer layer of PZT deposition according to the present invention.

FIG. 10 is a cross-sectional view of a field effect transistor wherein Pt electrode is inserted between the PZT and ZrTiO₄ according to the present invention.

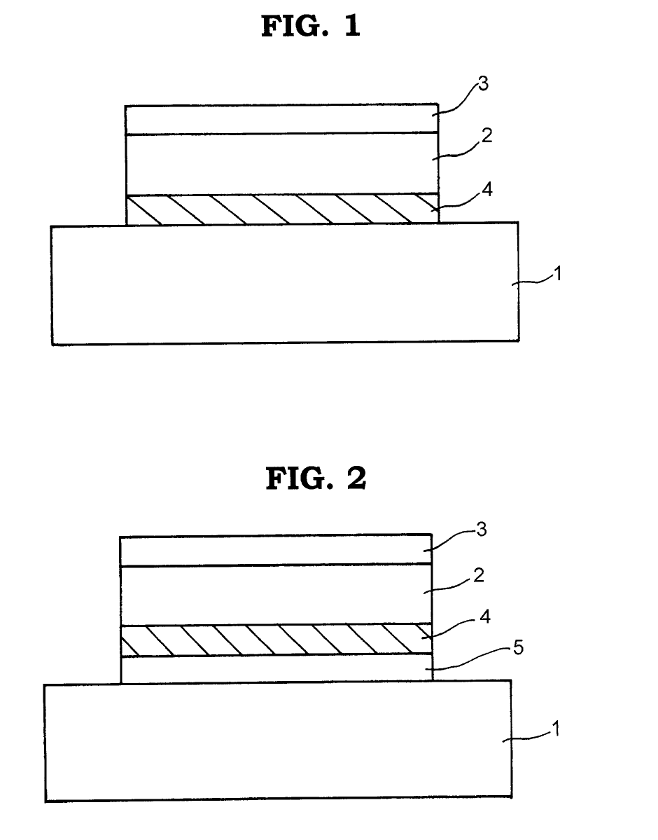

### DETAILED DESCRIPTION OF THE INVENTION

The use of PZT thin film for ferroelectrics in the manufacturing of a field effect transistor as a preferred embodiments of the invention will be described hereinafter with reference to the drawings.

Experimental Method

p-type (111) substrate is used for a Si substrate. ZrTiO₄ thin film and PZT thin film are deposited by RF reactive magnetron sputtering method and Pb, Zr and Ti metals are used for a target. Base pressure was below 1×10⁻⁵ Torr, the substrate temperature during deposition was maintained at 350° C. and working pressure was 20 mTorr. Mixed gas of Ar and O₂ in the volume ratio of 1:9 was used for sputtering gas. Tubular type furnace was used for an annealing of deposited thin film. Phase changes after annealing was observed using X-ray diffractometer.

AES(Auger electron spectroscopy) was used for an analysis of each element according to the depth of thin film and to observe Pb diffusion.

In order to measure electrical characteristics of the thin film, Pt was used for a top electrode, which was deposited by DC magnetron sputtering method using a shadow mask. The dielectric constant and capacitance-voltage characteristics of the thin film were measured at 1 MHz using HP4280A, and polarization was measured using RT66A.

### EXAMPLE 1

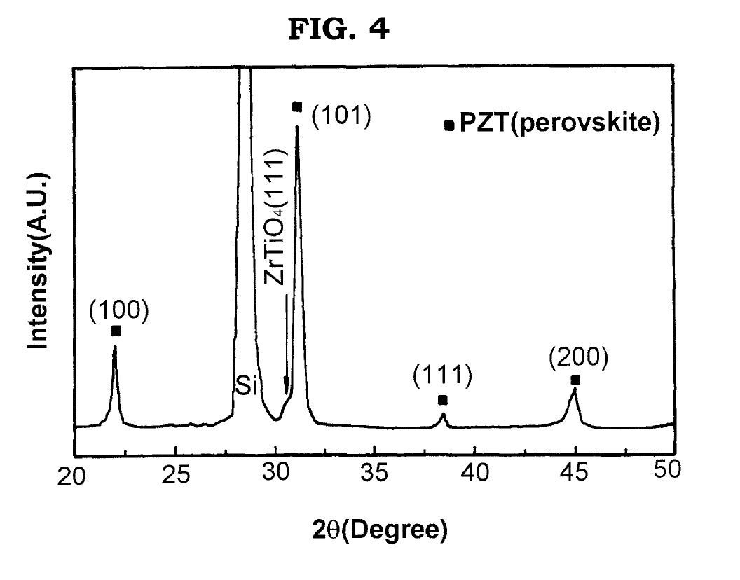

ZrTiO₄ thin film with thickness of 1500 Å was deposited on a Si substrate by a sputtering method and then the thin film was annealed at 800° C. for an hour under oxygen atmosphere for crystallization. PZT thin film with thickness of 2500 A was deposited on the ZrTiO₄ (1500 Å)/Si substrate and then the thin film was annealed at 600 ° C. for an hour under oxygen atmosphere for crystallization. The growth of rosette type perovskite phase observed in the general PZT/Pt structure was detected from the PZT/ZrTiO₄/Si thin film by a polarization microscope. Furthermore, the transformation of PZT thin film into perovskite phase on the ZrTiO₄/Si substrate was identified by an XRD analysis. The XRD analysis result is shown in FIG. 4.

As shown in FIG. 4, PZT phase of perovskite structure is formed nicely on the Si substrate deposited with ZrTiO₄. The ZrTiO₄ which blocks mutual diffusion and reaction between PZT and Si is thought to be the reason.

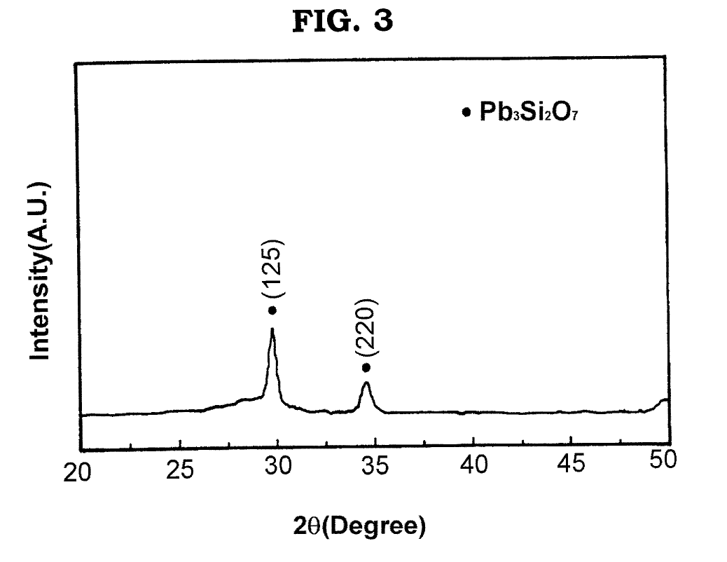

FIG. 3 is an XRD (X-ray diffraction) pattern of PZT thin film deposited on Si substrate by a sputtering method without forming a diffusion barrier layer. More specifically, it shows an XRD pattern of PZT thin film annealed at 600° C. under oxygen atmosphere after a direct deposition on a Si substrate at 350° C. As shown in FIG. 3, after a high temperature annealing for a crystallization of PZT thin film, crystalline thin film is not formed on a Si substrate due to a severe reaction with the substrate.

### EXAMPLE 2

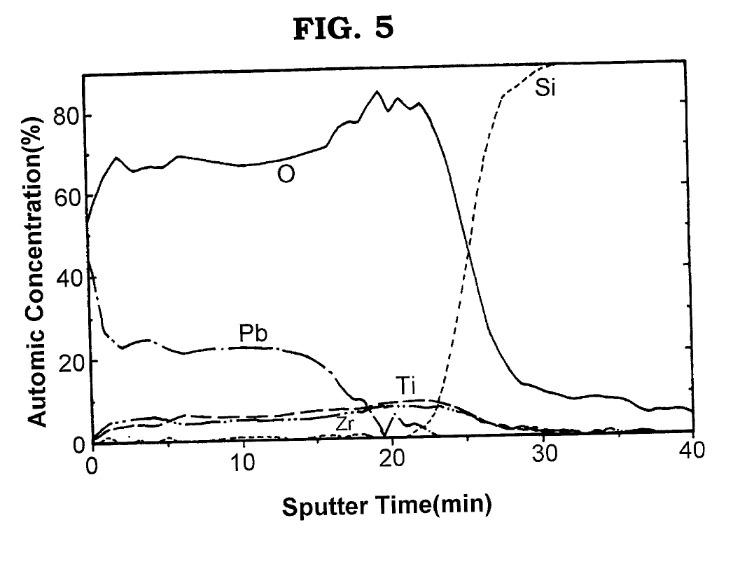

In order to test the Pb diffusion barrier capacity of ZrTiO₄ thin film, a sample of PZT(2500 Å)/ZrTiO₄(500 Å)/Si structure was manufactured and the sample was annealed at 600° C. for 30 minutes. The depth-profile was measured using AES and the result is shown in FIG. 5. FIG. 5 shows that there is no Pb inside Si due to an effective protection of Pb diffusion from the PZT thin film by ZrTiO₄ layer with thickness of 500 Å.

### EXAMPLE 3

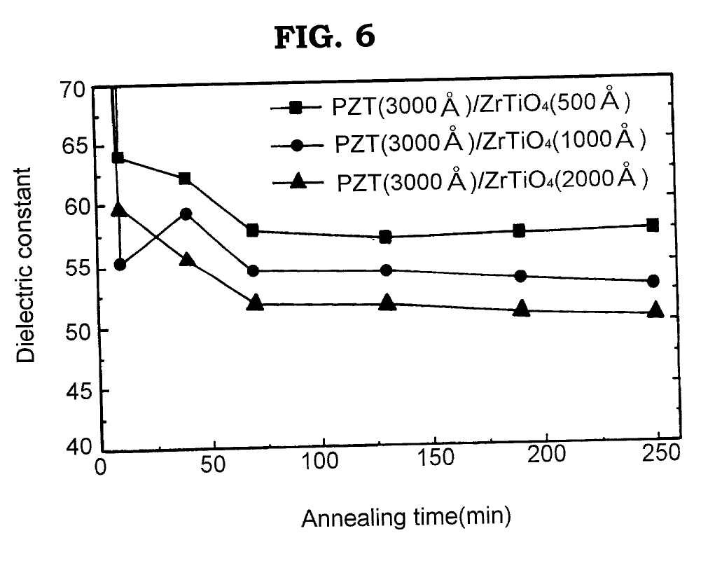

The dielectric constant of PZT/ZrTiO₄ thin film according to the thickness of ZrTiO₄ film and PZT crystallization time was measured by manufacturing samples of PZT/ZrTiO₄/Si structure with ZrTiO₄ at the thickness of 500, 1000 and 2000 Å. The top Pt electrode was formed with a diameter of 270 μm. Curing temperature was set to 600° C. which is general crystallization temperature of PZT, and the curing time was accumulated up to 250 minutes. FIG. 6 shows changes in dielectric constant according to the curing time and the thickness of ZrTiO₄ thin film. There is no change in the dielectric constant of PZT/ZrTiO₄ when the curing time is above 10 minutes, but the dielectric constant decreases according to the increase in the thickness of ZrTiO₄ thin film.

The experimental results showed that the dielectric constant is biggest for a sample with ZrTiO₄ film thickness of 500 Å and the dielectric constant of whole PZT/ZrTiO₄ decreases according to the increase of ZrTiO₄ film thickness, which corresponds to theoretical expectation. Considering the changes of dielectric constant, the reaction between PZT and Si can be protected when the thickness of ZrTiO₄ thin film is above 500 Å.

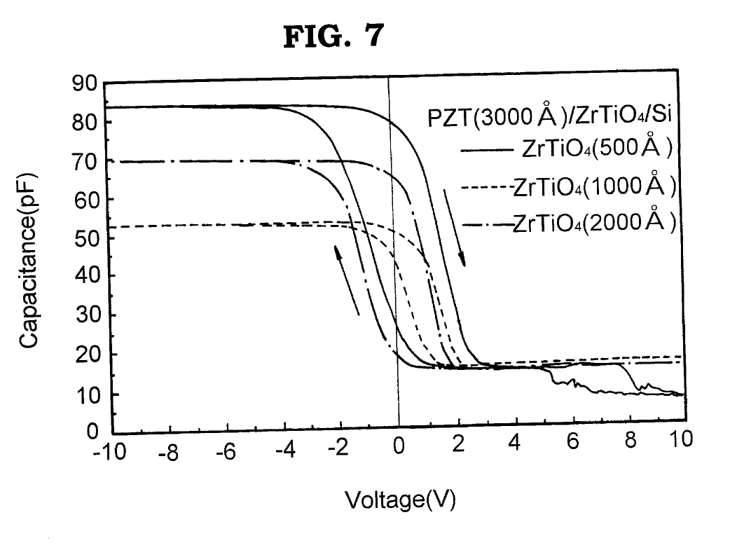

FIG. 7 shows a capacitance-voltage, C-V, curve when the samples of Pt/PZT(3000 Å)/ZrTiO₄/Si with ZrTiO₄ film thickness of 500, 1000, and 2000 Å are annealed at 600° C. for 70 minutes. The range of applied voltage was ±10 V, and capacitance was measured by applying from −10 V to +10 V and then +10 V to −10 V. The measurement frequency was 1 MHz.

As shown in FIG. 7, a clockwise C-V hysteresis curve due to polarization inversion of ferroelectrics was observed. The thinner the ZrTiO₄ is, the bigger the memory window (difference of threshold voltage value) is at the hysteresis curve, which can be explained by the following equation when the two dielectric layers of PZT and ZrTiO₄ are connected serially.

$${V}_{PZT} = \frac{{ϵ}_{ZT} \cdot {d}_{PZT}}{{ϵ}_{PZT} \cdot {d}_{ZT} + {ϵ}_{ZT} \cdot {d}_{PZT}} \cdot V$$

wherein V is applied voltage to the whole structure, V_{PZT} is applied voltage to PZT thin film, ∈_{PZT} and ∈_{ZT} are dielectric constant of PZT and ZrTiO₄, and d_{PZT} and d_{ZT} are thickness of PZT and ZrTiO₄, respectively. In the above equation, it is observed that as the thickness of ZrTiO₄ thin film decreases, the voltage applied to the PZT thin film increases.

Generally, as the voltage applied to the thin film of ferroelectrics increases the polarization and coercive voltage, Vc, increase. In the PZT/ZrTiO4 structure, the decrease of thickness of ZrTiO₄ thin film increases the voltage applied to the PZT thin film, which leads to increase in polarization of PZT thin film and coercive voltage resulting in increase in memory window. In the operation of MFISFET device of the present invention, the operation characteristics becomes clearer with increased memory window, and the memory window becomes as good as 2.5, 2.2 and 1.2V for the thickness of 500, 1000 and 2000 Å of ZrTiO₄, respectively.

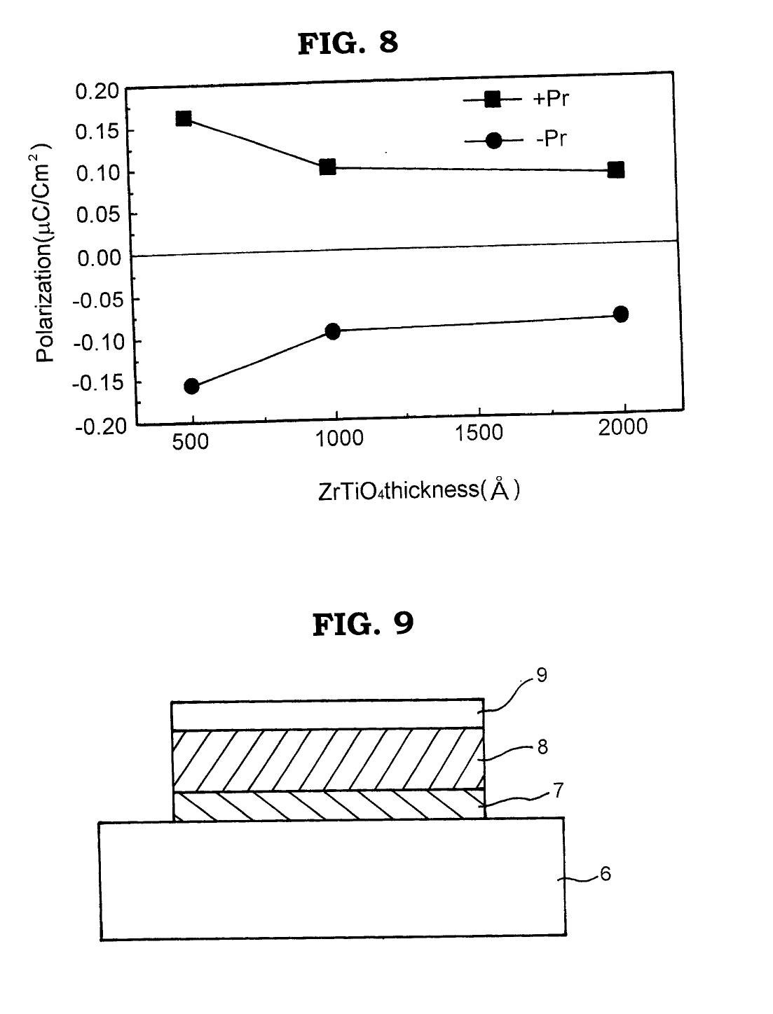

FIG. 8 shows residual polarization according to the thickness of ZrTiO₄ thin film from measuring the polarization-voltage, P-V, characteristics of the aforementioned samples. In FIG. 8, decrease in the thickness of ZrTiO₄ thin film results in increase in polarization, which can be explained by the increase in polarization according to the increase in voltage applied to the PZT thin film as described above. The polarization was 0.159, 0.097 and 0.086 μC/cm² for the thickness of 500, 1000 and 2000 Å of ZrTiO₄ respectively. These are very small values but as small as 0.1 μC/cm² polarization can lead to inversion layer of Si, and therefore, it can be found that the hysteresis curve in the C-V curve results from the polarization characteristics of ferroelectrics.

FIG. 9 is a cross-sectional view of a MFIS structure field effect transistor using ZrTiO₄ for a buffer layer. More specifically, the MFIS structure field effect transistor comprises a silicon substrate 6, ferroelectric PZT 8 formed on top of the substrate and a top electrode 9, and additionally a barrier layer of ZrTiO₄ 7 which s formed between the silicon substrate 6 and the ferroelectrics 8. On top of the silicon substrate 6, a bottom layer containing Si such as a gate insulator can be formed in addition.

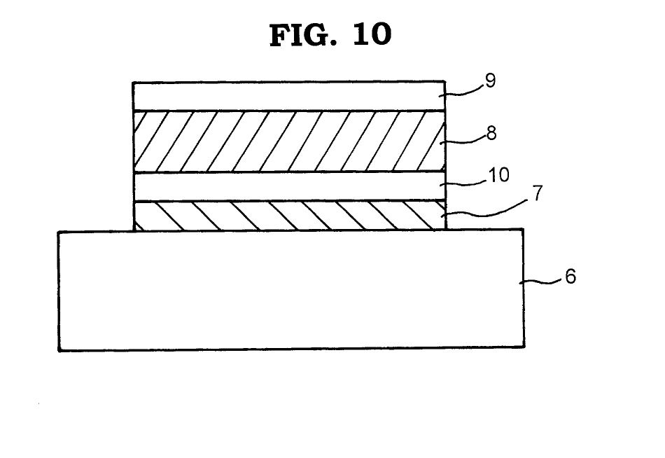

FIG. 10 is a cross-sectional view of an MFMIS structure field effect transistor wherein an electrode is formed between the ferroelectrics of the MFIS structure field effect transistor of FIG. 9 and a buffer layer. More specifically, the MFMIS structure field effect transistor comprises a silicon substrate 6, a buffer layer of ZrTiO₄ 7 formed on top of the substrate, ferroelectric PZT 8 and a top electrode 9, and there is a Pt thin fim 10 as an electrode between the buffer layer 7 and the ferroelectrics 8. On top of the silicon substrate 6, a bottom layer containing Si such as a gate insulator can be formed additionally.

The ZrTiO₄ layer 7 can be formed by a method such as Metal Organic Chemical Vapor Deposition (MOCVD), sputtering, sol-gel, Metal Organic Decomposition (MOD), evaporation or laser ablation.

Embodiments of the present invention are explained employing PZT thin film as ferroelectrics but it is not limited only to the above, and it is evident that it can be diversely modified such as ferroelectric SrBi₂Ta₂O₉ (SBT) or (BiₓLa₄₋ₓ)Ti₃O₁₂(BLT) with BiO₂ layer structure by a person who has ordinary knowledge in the appropriate field, within the technical idea of the present invention.

As explained above when ZrTiO₄ is used for a buffer layer to a ferroelectric thin film in the manufacture of a field effect transistor according to the present invention, the device shows superior interfacial and diffusion barrier characteristics between the ferroelectric thin film and the buffer layer. Furthermore, the characteristics of the device can be enhanced resulting from the increase in operation voltage applied to the ferroelectric buffer layer due to the use of ZrTiO₄ thin film with higher dielectric constant compared to other diffusion barrier layer.

What is claimed is:

1. A manufacturing method of a field effect transistor using zirconiumtitanate thin film comprising:
a step of forming ZrTiO₄ thin film on a semiconductor substrate as a buffer layer;
a step of forming a ferroelectric thin film on the buffer layer; and
a step of forming a top electrode on the ferroelectric thin film.

2. A manufacturing method of a field effect transistor using zirconiumtitanate thin film according to claim 1, wherein there is an additional step of forming a gate insulator between the semiconductor substrate and the buffer layer.

3. A manufacturing method of a field effect transistor using zirconiumtitanate thin film according to claim 1, wherein the ferroelectric thin film can be selected from PZT, SBT or BLT.

4. A manufacturing method of a field effect transistor using zirconiumtitanate thin film according to claim 1, wherein the ferroelectric thin film can be deposited by a method such as Metal Organic Chemical Vapor Deposition (MOCVD), sputtering, sol-gel, Metal Organic Decomposition (MOD), or laser ablation.

5. A manufacturing method of a field effect transistor using zirconiumtitanate thin film comprising:
a step of forming ZrTiO₄ thin film on a semiconductor substrate as a buffer layer;
a step of forming an electrode layer on the buffer layer;
a step of forming a ferroelectric thin film on the electrode layer; and
a step of forming a top electrode on the ferroelectric thin film.

6. A manufacturing method of a field effect transistor using zirconiumtitanate thin film according to claim 1, wherein the electrode layer is a Pt electrode layer.

7. A field effect transistor using zirconiumtitanate thin film comprising:
a semiconductor substrate;
a buffer layer formed of zirconiumtitanate on the semiconductor substrate;
a ferroelectric thin film formed on the buffer layer; and
a top electrode formed on the ferroelectric thin film.

8. A field effect transistor using zirconiumtitanate thin film according to claim 7, wherein there is a gate insulator formed between the semiconductor substrate and the buffer layer.

9. A field effect transistor using zirconiumtitanate thin film according to claim 7, wherein the ferroelectric thin film can be selected from PZT, SBT or BLT.

10. A field effect transistor using zirconiumtitanate thin film according to claim 7, wherein the ferroelectric thin film can be deposited by a method such as Metal Organic Chemical Vapor Deposition (MOCVD), sputtering, sol-gel, Metal Organic Decomposition (MOD), or laser ablation.

11. A field effect transistor using zirconiumtitanate thin film comprising:
a semiconductor substrate;
a buffer layer formed of ZrTiO₄ on the semiconductor substrate;
an electrode layer formed on the buffer layer;
a ferroelectric thin film formed on the electrode layer; and
a top electrode formed on the ferroelectric thin film.

12. A field effect transistor using zirconiumtitanate thin film according to claim 11, wherein the electrode layer is a Pt electrode layer.

13. A field effect transistor using zirconiumtitanate thin film according to claim 11, wherein the ZrTiO₄ thin film can be deposited by a method such as Metal Organic Chemical Vapor Deposition (MOCVD), sputtering, sol-gel, Metal Organic Decomposition (MOD), or laser ablation.

14. A manufacturing method of a field effect transistor using zirconiumtitanate thin film according to claim 1, wherein the ZrTiO₄ thin film can be deposited by a method such as Metal Organic Chemical Vapor Deposition (MOCVD), sputtering, sol-gel, Metal Organic Decomposition (MOD), or laser ablation.
